(19) United States
(12) Patent Application Publication
(10) Pub. No.: US 2024/0272212 A1
(43) Pub. Date: Aug. 15, 2024

(54) MOTOR DRIVE DEVICE CALCULATING INSULATION RESISTANCE VALUE OF MOTOR

(71) Applicant: Fanuc Corporation, Minamitsuru-gun, Yamanashi (JP)

(72) Inventor: Taku Sasaki, Minamitsuru-gun, Yamanashi (JP)

(73) Assignee: Fanuc Corporation, Minamitsuru-gun, Yamanashi (JP)

(21) Appl. No.: 18/566,790

(22) PCT Filed: Jun. 16, 2021
(86) PCT No.: PCT/JP2021/022879

§ 371 Date: Dec. 4, 2023

(51) Int. Cl. G01R 27/02; G01R 31/34; H02P 23/14; H02P 27/06

(52) U.S. Cl. CPC G01R 27/025; G01R 31/343; H02P 23/14; H02P 27/06

(57) ABSTRACT

This motor drive device includes an insulation resistance value detection unit for detecting the insulation resistance value of a motor on the basis of the measured value of the inter-terminal voltage of a measurement resistor and the resistance value of the measurement resistor; and a failure determination unit for determining, on the basis of the error between the measured and estimated values of the inter-terminal voltage of the measurement resistor, the presence or absence of a failure of the insulation resistance value detection unit for detecting the insulation resistance value of the motor.

### CROSS REFERENCE TO RELATED APPLICATIONS

This is the U.S. National Phase application of PCT/JP2021/022879, filed Jun. 16, 2021, the disclosure of this application being incorporated herein by reference in its entirety for all purposes.

### FIELD OF THE INVENTION

The present invention relates to a motor drive device configured to calculate an insulation resistance value of a motor.

### BACKGROUND OF THE INVENTION

In a servomotor provided in a machine tool or the like, a resistance value of an insulation resistor (insulation resistance value) of a motor coil (winding) relative to the ground decreases over time due to intrusion of oil or the like. When the insulation resistance value of the motor coil decreases, the leak current will flow through a closed circuit consisting of a motor, a motor drive device, and the ground. Since the leak current flows through the motor drive device in addition to electric current for driving the motor, a servo amplifier may perform an overcurrent detection operation, or a breaker provided in an input stage may trip. As a result, the machine tool provided with the motor may be caused to emergently shut down. When such an emergency shutdown occurs, the machine tool may be stopped over a long period of time for investigation into the cause, which reduces efficiency. Therefore, a task of measuring the insulation resistance value of the motor is indispensable in operating the motor drive device.

For example, there is known a method of detecting deterioration of an insulation resistance of a motor driven by a motor drive device including: a power supply unit configured to rectify, with a rectifier circuit, electrical power supplied from an AC power supply via a switch and smooth the electrical power with a capacitor; and a motor driver amplifier configured to convert a DC voltage from the power supply unit into an AC voltage to drive the motor, wherein after the switch is turned off and operation of the motor is stopped, one end of the capacitor is connected to the ground while the other end of the capacitor is connected to a motor coil, and deterioration of the insulation resistance of the motor is detected by detecting an electric current flowing through a closed circuit consisting of the capacitor, the motor coil, and the ground (for example, see PTL 1).

For example, there is known a motor drive device having a function of detecting a failure of an insulation resistance deterioration detection unit of a motor, the motor drive device including: a power supply unit configured to rectify an AC voltage supplied from an AC power supply via a switch into a DC voltage with a rectifier circuit and smooth the rectified DC voltage with a capacitor; a motor drive amplifier unit configured to convert the DC voltage from the power supply unit into an AC voltage using switching elements in an upper arm and a lower arm to drive the motor; a power supply voltage measurement unit configured to measure a voltage of the power supply unit; an insulation resistance deterioration detection unit including a contact portion for connecting one end of the capacitor to the ground and an electric current detection unit placed between the other end of the capacitor and a motor coil, the insulation resistance deterioration detection unit configured to detect whether or not an insulation resistance of the motor has deteriorated in a condition where the switch is set in an OFF state and the contact portion is set in an ON state, using the electric current detection unit, on the basis of a detection signal obtained from a closed circuit consisting of the contact portion, the capacitor, the motor coil, and the ground; and a failure detection unit configured to detect whether or not the insulation resistance deterioration detection unit has failed, in a condition where the contact portion is set from the ON state to an OFF state and the switching elements of the upper arm or the lower arm of the motor drive amplifier unit are switched as desired, on the basis of the detection signal obtained by the insulation resistance deterioration detection unit and a value of the voltage measured by the power supply voltage measurement unit (for example, see PTL 2).

For example, there is known a detection device configured to detect insulation deterioration of a motor connected to a motor drive device that includes a converter unit including a rectifier circuit for rectifying an AC power supply, a smoothing capacitor for smoothing an output from the rectifier circuit, and a plurality of inverter units for converting a direct current output from the converter unit into an alternate current to individually drive a plurality of motors, the detection device including: one first switch configured to be electrically connected when insulation deterioration is detected to ground one end of the smoothing capacitor; one voltage detection unit configured to measure a voltage across both ends of the smoothing capacitor; a plurality of second switches configured to be electrically connected when insulation deterioration is detected to connect the other end of the smoothing capacitor individually to windings of the plurality of motors; a plurality of electric current detection units configured to detect a discharge current of the smoothing capacitor that flows through an insulation resistor of each of the plurality of motors when the first switch and the plurality of second switches are electrically connected; and a plurality of insulation resistance calculation units configured to calculate an insulation resistance of each of the plurality of motors from a voltage detected by the voltage detection unit and an electric current detected by each of the plurality of electric current detection units, wherein the one first switch and the one voltage detection unit are provided in the converter unit, the plurality of second switches, the plurality of electric current detection units, and the plurality of insulation resistance calculation units are provided in the plurality of inverter units, the detection device further including a communication means for transmitting the value of the voltage detected by the one voltage detection unit and a signal for notifying a timing for turning on the one first switch from the converter unit to the plurality of inverter units, wherein in each of the plurality of inverter units, connection by the second switch, detection of the electric current by the electric current detection unit, and calculation of the insulation resistance by the insulation resistance calculation unit are performed at the same time at the same timing (for example, see PTL 3).

For example, there is known a motor drive device including: a rectifier circuit configured to rectify an AC voltage supplied from an AC power supply via a first switch into a DC voltage; a power supply unit configured to smooth the DC voltage rectified by the rectifier circuit with a capacitor; an inverter unit configured to convert the DC voltage that has been smoothed by the power supply unit into an AC voltage by a switching operation of a semiconductor switching device to drive a motor; an electric current detection unit configured to measure a value of an electric current flowing through a resistor, one end of which is connected to a coil of the motor and the other end of which is connected to one terminal of the capacitor; a voltage detection unit configured to measure a value of a voltage across both ends of the capacitor; a second switch configured to ground the other terminal of the capacitor; and an insulation resistance detection unit configured to detect an insulation resistance of the motor, using two sets of values of the electric currents and the voltages measured when operation of the motor is stopped with the first switch being turned OFF in two conditions, i.e., the second switch being turned OFF and the second switch being turned ON, the insulation resistance being a resistance between the coil of the motor and the ground (for example, see PTL 4).

For example, there is known an isolation detector connected between one of a P-bus and a N-bus of an electrical device, the electrical device including a rectifier circuit that is disposed between an AC power supply and a load and converts an AC voltage into a DC voltage and an inverter that is connected to the rectifier circuit as a subsequent stage and drives the load, and an output line that connects the inverter to the load, the isolation detector including: a resistor constructed from a detecting resistor and a voltage-dividing resistor connected to each other in series; a capacitor connected in parallel to the resistor and having an impedance lower than that of the detecting resistor; a voltage sensor configured to measure a value of a voltage between both ends of the isolation detector by detecting the voltage across the detecting resistor after voltage dividing by the voltage-dividing resistor, wherein an insulation resistance between the load and the ground or an enclosure is detected from the value of the voltage across both ends of the isolation detector measured by the voltage sensor without the isolation detector being separated from the AC power supply (for example, see PTL 5).

### PATENT LITERATURE

[PTL 1] JP 4554501B
[PTL 2] JP 5832578B
[PTL 3] JP 4565036B
[PTL 4] JP 5788538B
[PTL 5] JP 2017-142269A

### SUMMARY OF THE INVENTION

When the insulation resistance detection circuit of the motor fails, the insulation resistance value cannot be accurately measured. Even if a failure detection circuit for detecting a failure of the insulation resistance detection circuit is provided, a measurement error of the insulation resistance detection circuit will be gradually increased due to aging before the failure detection circuit detects a failure of the insulation resistance detection circuit, which makes accurate measurement of the insulation resistance value increasingly difficult. Therefore, it is desired to provide a technique for correctly detecting a failure of a circuit for detecting the insulation resistance value of the motor and accurately detecting the insulation resistance value of the motor.

According to one aspect of the present disclosure, a motor drive device includes: a first switch configured to open/close an electrical path from an AC power supply; a power supply unit configured to rectify an AC voltage supplied from the AC power supply via the first switch in a closed state into a DC voltage with a rectifier circuit and smooth the rectified DC voltage with a capacitor; a motor drive amplifier unit configured to convert the DC voltage from the power supply unit into an AC voltage for driving a motor using switching elements in an upper arm and a lower arm and supply the AC voltage to the motor; a first voltage measurement unit configured to obtain a measured value of a voltage of the power supply unit; an insulation resistance value detection unit including a second switch configured to connect one end of the capacitor to the ground in a closed state and disconnect the one end of the capacitor from the ground in an open state, a measuring resistor placed between the other end of the capacitor and a motor coil, a second voltage measurement unit configured to obtain a measured value of a voltage between terminals of the measuring resistor, and a calculation unit configured to calculate an insulation resistance value of the motor based on the measured value of the voltage of the power supply unit obtained by the first voltage measurement unit, the measured value of the voltage between the terminals of the measuring resistor obtained by the second voltage measurement unit, and a resistance value of the measuring resistor, the measured value of the voltage of the power supply unit and the measured value of the voltage between the terminals of the measuring resistor being obtained when a first closed circuit is formed by setting the first switch and the second switch in the open state and the closed state respectively, the first closed circuit including the second switch, the capacitor, the measuring resistor, the motor coil, and the ground; a voltage estimation unit configured to calculate an estimated value of the voltage between the terminals of the measuring resistor based on the measured value of the voltage of the power supply unit obtained by the first voltage measurement unit and the resistance value of the measuring resistor, the measured value of the voltage of the power supply unit being obtained when a second closed circuit including the capacitor and the measuring resistor is formed by setting the first switch and the second switch in the open state and by switching the switching elements of the upper arm or the lower arm of the motor driver amplifier as desired; an error detection unit configured to detect an error between the measured value of the voltage between the terminals of the measuring resistor, which has been obtained by the second voltage measurement unit when the second closed circuit is formed and the estimated value of the voltage between the terminals of the measuring resistor, which has been calculated by the voltage estimation unit; and a failure determination unit configured to determine whether or not the insulation resistance value detection unit has failed on the basis of the error detected by the error detection unit.

According to one aspect of the present disclosure, the motor drive device can be achieved, the motor drive device being configured to correctly detect a failure of a circuit for detecting the insulation resistance value of the motor and accurately detect the insulation resistance value of the motor.

### BRIEF DESCRIPTION OF DRAWINGS

FIG. 1 is a diagram illustrating a motor drive device according to one embodiment of the present disclosure.

FIG. 2 is a diagram describing a second closed circuit that is formed when executing a processing of determining whether or not an insulation resistance value detection unit has failed in the motor drive device according to one embodiment of the present disclosure.

FIG. 3 is a flowchart illustrating operation sequences in the processing of determining whether or not the insulation resistance value detection unit has failed in the motor drive device according to one embodiment of the present disclosure.

FIG. 4 is a diagram describing a first closed circuit that is formed when executing the processing of detecting an insulation resistance value by the insulation resistance value detection unit in the motor drive device according to one embodiment of the present disclosure.

FIG. 5 is a flowchart (part 1) illustrating operation sequences in the processing of detecting the insulation resistance value by the insulation resistance value detection unit in the motor drive device according to one embodiment of the present disclosure.

FIG. 6 is a flowchart (part 2) illustrating operation sequences in the processing of detecting the insulation resistance value by the insulation resistance value detection unit in the motor drive device according to one embodiment of the present disclosure.

FIG. 7 is a circuit diagram in which a portion related to the first closed circuit is depicted.

FIG. 8 is a diagram illustrating a variation example of the motor drive device according to one embodiment of the present disclosure.

FIG. 9 is a flowchart illustrating operation sequences in the processing of determining whether or not an insulation resistance value detection unit has failed in the variation example of the motor drive device according to one embodiment of the present disclosure.

### DETAILED DESCRIPTION OF EMBODIMENTS OF THE INVENTION

With reference to the drawings, a motor drive device configured to calculate an insulation resistance value of a motor will be described below. In each drawing, the same kind of members are denoted by the same kind of reference signs. To facilitate understanding, these drawings use different scales as appropriate. An embodiment illustrated in the drawings is one example for implementing the present disclosure, and the present disclosure is not limited to the illustrated embodiment.

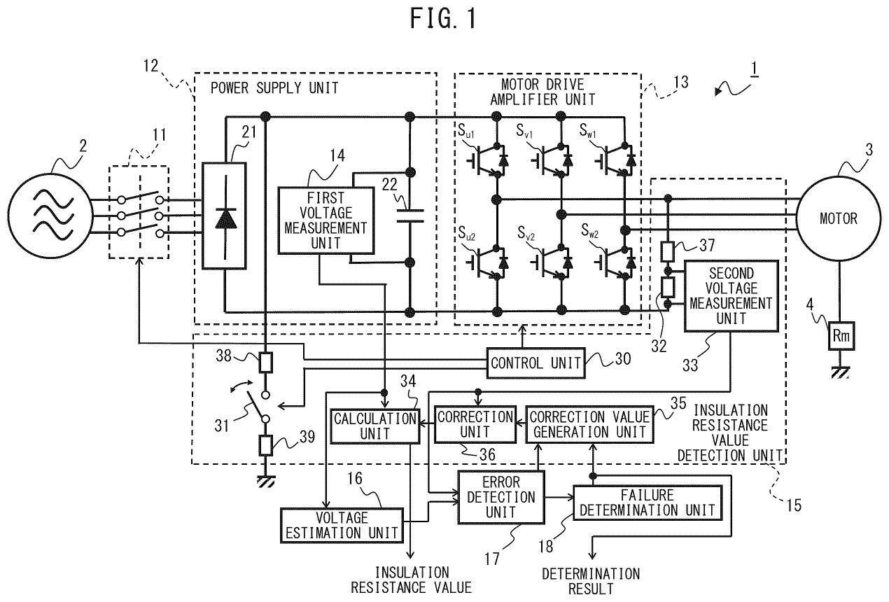

FIG. 1 is a diagram illustrating a motor drive device according to one embodiment of the present disclosure.

As an example, a case is illustrated in which a motor 3 is controlled by a motor drive device 1 connected to an AC power supply 2. In the present embodiment, a type of the motor 3 is not particularly limited, and it may be an induction motor or a synchronous motor. The number of phases of the AC power supply 2 and the motor 3 is not particularly limited in the present embodiment, and the number of phases may be, for example, three phases or a single phase. Examples of machinery provided with the motor 3 include, for example, machine tools, robots, forming machines, injection molding machines, industrial machinery, various types of electrical appliances, trains, automobiles, and aircraft. Examples of the AC power supply 2 include a three-phase 400 V AC power supply, a three-phase 200 V AC power supply, a three-phase 600 V AC power supply, and a single-phase 100 V AC power supply. In the illustrated example, both of the AC power supply 2 and the motor 3 are three-phase.

There is an insulation resistor 4 between a motor coil (winding) of the motor 3 and the ground. A resistance value of the insulation resistor 4, i.e., an insulation resistance value Rm [Ω] is infinite if it is not deteriorated and gradually decreases, for example, based on infinity to several megohm, several hundred kilo ohms, or the like, as it is deteriorated. The motor drive device 1 according to one embodiment of the present disclosure has a function of detecting the insulation resistance value Rm [Ω] of the motor 3 and a function of determining whether or not the function of detecting the insulation resistance value Rm [Ω] has failed.

As illustrated in FIG. 1, the motor drive device 1 according to one embodiment of the present disclosure includes: a first switch 11; a power supply unit 12; a motor drive amplifier unit 13; a first voltage measurement unit 14; an insulation resistance value detection unit 15; a voltage estimation unit 16; an error detection unit 17; and a failure determination unit 18.

The first switch 11 opens/closes an electrical path between an AC power supply 2 and a rectifier circuit 21 in the power supply unit 12. Opening/closing of the electrical path by the first switch 11 is controlled, for example, by a control unit 30 in the insulation resistance value detection unit 15; alternatively, it may be controlled by any given control unit (not illustrated) including an arithmetic processing unit, the control unit being provided externally to the insulation resistance value detection unit 15. The first switch 11 is constructed from, for example, a magnetic contactor. A closed state for the electrical path between the AC power supply 2 and the rectifier circuit 21 in the power supply unit 12 is achieved by closing a contact of the first switch 11, the first switch 11 being a magnetic contactor, while an open state for the electrical path between the AC power supply 2 and the rectifier circuit 21 in the power supply unit 12 is achieved by opening the contact of the first switch 11, the first switch 11 being a magnetic contactor. It should be noted that the first switch 11 may be, for example, a relay or a semiconductor switching device instead of a magnetic contactor as long as it can open/close the electrical path from the AC power supply 2.

The power supply unit 12 is connected to the motor drive amplifier unit 13 via a DC link. A “DC link” refers to a portion of a circuit that electrically connects a DC output terminal of the power supply unit 12 to a DC input terminal of the motor drive amplifier unit 13, and it may be referred to as a “DC link unit”, a “direct current link”, a “direct current link unit”, a “direct current intermediate circuit”, or the like.

The power supply unit 12 includes the rectifier circuit 21 and a capacitor 22, rectifies an AC voltage supplied from the AC power supply 2 via the first switch 11 in the open state into a DC voltage with the rectifier circuit 21, smooths the rectified DC voltage with the capacitor 22, and outputs the resultant DC voltage.

The rectifier circuit 21 in the power supply unit 12 may be, for example, a diode rectifier circuit, a 120-degree conduction type rectifier circuit, or a rectifier circuit including switching elements inside employing a PWM switching control method as long as it can convert an AC voltage into a DC voltage. When the AC power supply 2 is a three-phase AC power supply, the rectifier circuit 21 is constructed as a three-phase bridge circuit; when the AC power supply 2 is a single-phase AC power supply, the rectifier circuit 21 is constructed as a single-phase bridge circuit. When the rectifier circuit 21 is a rectifier circuit employing a PWM switching control method, the rectifier circuit 21 is constructed from a bridge circuit including switching elements and diodes connected in antiparallel to the switching elements. In this case, examples of the switching elements include an IGBT, a thyristor, a GTO (gate turn-off thyristor), and a transistor although the type of the switching element itself does not limit the present embodiment and other types of switching elements may be used.

The capacitor 22 in the power supply unit 12 has a function of smoothing the DC voltage output by the rectifier circuit 21 and a function of accumulating the DC power in the DC link. The capacitor 22 may be also referred to as a smoothing capacitor or a DC link capacitor. Examples of the capacitor 22 include, for example, an electrolytic capacitor and a film capacitor.

The first voltage measurement unit 14 is connected to positive and negative terminals of the capacitor 22. The first voltage measurement unit 14 is a measuring circuit for obtaining a measured value of a (DC) voltage of the power supply unit 12, the voltage being applied to the capacitor 22.

The motor drive amplifier unit 13 includes an inverter constructed from a bridge circuit including a set of switching elements and diodes connected in antiparallel to the switching elements disposed in an upper arm and a lower arm. In the illustrated example, since the motor 3 is assumed to be a three-phase AC motor, the inverter in the motor drive amplifier unit 13 is constructed from a three-phase bridge circuit. It is assumed here that the switching elements in the upper arm and the lower arm of the U-phase are respectively Su1 and Su2, the switching elements in the upper arm and the lower arm of the V-phase are respectively Sv1 and Sv2, and the switching elements in the upper arm and the lower arm of the W- are is respectively Sw1 and Sw2.

The motor drive amplifier unit 13 performs power conversion operation in response to a PWM switching command from a higher-level controller (not illustrated) for controlling on-off operations of the switching elements in the upper arm and the lower arm. In other words, the motor drive amplifier unit 13 converts a DC voltage at the DC link into an AC voltage for driving the motor as a result of the on-off operations of the switching elements in the upper arm and the lower arm, and supplies the AC voltage to the motor 3; in addition, during regeneration period of the motor, the motor drive amplifier unit 13 converts the AC voltage regenerated by the motor 3 into a DC voltage and returns the DC voltage to the DC link. In one embodiment of the present disclosure, on-off operations of the switching elements in the upper arm and the lower arm of the motor drive amplifier unit 13 are also controlled by the control unit 30 of the insulation resistance value detection unit 15, and details thereof will be described below.

The insulation resistance value detection unit 15 detects the insulation resistance value Rm [Ω] that is a resistance value of the insulation resistor 4 between the motor coil (winding) of the motor 3 and the ground. The insulation resistance value detection unit 15 includes: the control unit 30, a second switch 31, a measuring resistor 32, a second voltage measurement unit 33, a calculation unit 34, a correction value generation unit 35, and a correction unit 36. Detection of the insulation resistance value Rm [Ω] of the insulation resistor 4 of the motor 3 by the insulation resistance value detection unit 15 is performed using various types of data with respect to a first closed circuit obtained by setting the first switch 11 and the second switch 31 in the open state and the closed state respectively and by setting all the switching elements in the motor drive amplifier unit 13 in the OFF state. The first closed circuit is a closed circuit for detecting the insulation resistance value and includes the second switch 31, the capacitor 22, the measuring resistor 32, the motor coil of the motor 3, and the ground.

One terminal of the second switch 31 in the insulation resistance value detection unit 15 is connected to a voltage-dividing resistor 38 while the other terminal of the second switch 31 is connected to a voltage-dividing resistor 39. One terminal of the voltage-dividing resistor 38 is connected to a positive power line that connects the rectifier circuit 21 to the capacitor 22 in the power supply unit 12. One terminal of the voltage-dividing resistor 39 is connected to the ground. Grounding is controlled by an open/close operation of the second switch 31; in other words, when the second switch 31 is in the closed state, a positive terminal of the capacitor 22 is connected to the ground, and when the second switch 31 is in the open state, one end of the capacitor is not connected to the ground. Opening/closing of the second switch 31 is controlled by the control unit 30. The second switch 31 is constructed from, for example, a relay, a semiconductor switching device, or a magnetic contactor.

The measuring resistor 32 is placed between a negative terminal of the capacitor 22 and the motor coil of the motor 3. More specifically, one terminal of the measuring resistor 32 is connected to the negative terminal of the capacitor 22 via a negative power line of the motor drive amplifier unit 13. The other terminal of the measuring resistor 32 is connected, via a voltage-dividing resistor 37, to a power line for one phase that connects the motor drive amplifier unit 13 to the motor coil of the motor 3. In the illustrated example, the other terminal of the measuring resistor 32 is connected, as an example, to a U-phase power line that connects the motor drive amplifier unit 13 to a U-phase motor coil of the motor 3. The second voltage measurement unit 33 is a measuring circuit for obtaining a measured value of a voltage between the terminals (i.e., inter-terminal voltage) of the measuring resistor 32. For example, it may be constructed from an isolated amplifier consisting of the measuring resistor 32, the second voltage measurement unit 33, and the voltage-dividing resistor 37. The voltage-dividing resistor 37 is provided for adjusting an input voltage for the isolated amplifier within an appropriate range.

The correction value generation unit 35 generates a correction value based on an error detected by the error detection unit 17 that is used when the failure determination unit 18 to be described below determines that the insulation resistance value detection unit 15 has not failed.

The correction unit 36 corrects the measured value of the voltage between the terminals of the measuring resistor 32, which has been obtained by the second voltage measurement unit 33 when the first closed circuit is formed, using the correction value generated by the correction value generation unit 35, and generates a corrected value of the measured value of the voltage between the terminals of the measuring resistor 32. The corrected value of the measured value of the voltage between the terminals of the measuring resistor 32 generated by the correction unit 36 is used by the calculation unit 34 for the calculation of the insulation resistance value Rm [Ω] of the motor 3.

The calculation unit 34 calculates, when the first closed circuit including the second switch 31, the capacitor 22, the measuring resistor 32, the motor coil of the motor 3, and the ground is formed, the insulation resistance value Rm [Ω] of the insulation resistor 4 of the motor 3 based on the measured value of the voltage of the power supply unit 12, which has been obtained by the first voltage measurement unit 14, the corrected value of the measured value of the voltage between the terminals of the measuring resistor 32 generated by the correction unit 36, and the resistance value of the measuring resistor 32. The processing of calculating the insulation resistance value by the calculation unit 34 will be described in detail below.

The insulation resistance value of the motor 3 detected by the insulation resistance value detection unit 15 is transmitted to a display unit (not illustrated), and the display unit displays “the insulation resistance value of the motor 3” to notify an operator of the value. Examples of the display unit include a stand-alone display device, a display device accompanying the motor drive device 1, a display device accompanying a higher-level controller (not illustrated), and a display device accompanying a personal computer or a mobile terminal. Alternatively, the insulation resistance value of the motor 3 detected by the insulation resistance value detection unit 15 may be transmitted, for example, to an alarm output unit (not illustrated), and the alarm output unit may output an insulation resistance deterioration alarm when the insulation resistance value of the motor 3 is less than a predetermined value. The insulation resistance deterioration alarm output from the alarm output unit is transmitted, for example, to a light-emitting device (not illustrated), such as an LED or a lamp, and the light-emitting device emits light upon receiving the insulation resistance deterioration alarm to notify the operator of “deterioration of the insulation resistor 4 of the motor 3”. In addition, the insulation resistance deterioration alarm output from the alarm output unit is transmitted, for example, to a sound device (not illustrated), and the sound device emits a sound of, for example, a speaker, a buzzer, a chime, or the like, upon receiving the insulation resistance deterioration alarm to notify the operator of “deterioration of the insulation resistor 4 of the motor 3”. With this operation, the operator can certainly and easily understand deterioration of the insulation resistance value of the motor 3 or the insulation resistor 4 of the motor 3, and can easily take action such as replacing the motor 3 or dismounting and cleaning the motor 3.

Determination of whether or not the insulation resistance value detection unit 15 has failed is performed using various types of data with respect to a second closed circuit obtained by setting the first switch 11 and the second switch 31 in the open state and by switching the switching elements in the upper arm or the lower arm of the motor drive amplifier unit 13 as desired. The second closed circuit is a closed circuit for determining a failure and includes the capacitor 22 and the measuring resistor 32.

The voltage estimation unit 16 calculates an estimated value of the voltage between the terminals of the measuring resistor 32 according to a circuit equation with respect to the second closed circuit including the capacitor 22 and the measuring resistor 32, the equation obtained by setting the first switch 11 and the second switch 31 in the open state and by switching the switching elements in the upper arm or the lower arm of the motor drive amplifier unit 13 as desired, based on the measured value of the voltage of the power supply unit 12, which has been obtained by the first voltage measurement unit 14 and the resistance value of the measuring resistor 32.

The error detection unit 17 detects an error between the measured value of the voltage between the terminals of the measuring resistor 32, which has been obtained by the second voltage measurement unit 33 when the second closed circuit is formed, and the estimated value of the voltage between the terminals of the measuring resistor 32, which has been calculated by the voltage estimation unit 16. The error detected by the error detection unit 17 is used in failure determination processing by the failure determination unit 18 and correction value generation processing by the correction value generation unit 35. It should be noted that “the measured value of the voltage between the terminals of the measuring resistor 32, which has been obtained by the second voltage measurement unit 33”, which is used in the processing of detecting an error by the error detection unit 17 is not a value corrected by the correction unit 36.

The failure determination unit 18 determines whether or not the insulation resistance value detection unit 15 has failed on the basis of the error detected by the error detection unit 17. More specifically, the failure determination unit 18 determines that the insulation resistance value detection unit 15 has failed when the error detected by the error detection unit 17 is out of a predefined reference error range and determines that the insulation resistance value detection unit 15 has not failed when the error detected by the error detection unit 17 is within the reference error range.

The determination result by the failure determination unit 18 is used in the correction value generation processing by the correction value generation unit 35.

The determination result by the failure determination unit 18 may be optionally transmitted to the display unit (not illustrated). In this case, the display unit displays “whether or not the insulation resistance value detection unit 15 has failed” to notify the operator. Examples of the display unit include a stand-alone display device, a display device accompanying the motor drive device 1, a display device accompanying a higher-level controller (not illustrated), and a display device accompanying a personal computer or a mobile terminal. Alternatively, the determination result that the insulation resistance value detection unit 15 has failed may be transmitted, for example, to the alarm output unit (not illustrated), and the alarm output unit may output a failure detection alarm upon receiving a determination result that the insulation resistance value detection unit 15 has failed. The failure detection alarm output from the alarm output unit is transmitted, for example, to a light-emitting device (not illustrated), such as an LED or a lamp, and the light-emitting device emits light upon receiving the failure detection alarm to notify the operator that “the insulation resistance value detection unit 15 has failed”. In addition, the failure detection alarm output from the alarm output unit is transmitted, for example, to a sound device (not illustrated), and the sound device emits a sound of, for example, a speaker, a buzzer, a chime, or the like, upon receiving the failure detection alarm to notify the operator that “the insulation resistance value detection unit 15 has failed”. With this operation, the operator can certainly and easily understand that the insulation resistance value detection unit 15 has failed, and can easily take action such as replacing the insulation resistance value detection unit 15.

In the motor drive device 1, an arithmetic processing unit (processor) is provided. Examples of the arithmetic processing unit include an IC, an LSI, a CPU, an MPU, and a DSP. The arithmetic processing unit includes: the first voltage measurement unit 14, the control unit 30, the second voltage measurement unit 33, the calculation unit 34, the correction value generation unit 35, the correction unit 36, the voltage estimation unit 16, the error detection unit 17, and the failure determination unit 18. Each of these units included in the arithmetic processing unit is a functional module achieved by, for example, a computer program executed by the processor. For example, when the first voltage measurement unit 14, the control unit 30, the second voltage measurement unit 33, the calculation unit 34, the correction value generation unit 35, the correction unit 36, the voltage estimation unit 16, the error detection unit 17, and the failure determination unit 18 are built in the form of a computer program, functions of the respective units may be achieved by causing the arithmetic processing unit to operate in accordance with the computer program. The computer program for executing processing by the first voltage measurement unit 14, the control unit 30, the second voltage measurement unit 33, the calculation unit 34, the correction value generation unit 35, the correction unit 36, the voltage estimation unit 16, the error detection unit 17, and the failure determination unit 18 may be recorded on and supplied in the form of a computer-readable recording medium, such as a semiconductor memory, a magnetic recording medium, or an optical recording medium. Alternatively, the functions of the first voltage measurement unit 14, the control unit 30, the second voltage measurement unit 33, the calculation unit 34, the correction value generation unit 35, the correction unit 36, the voltage estimation unit 16, the error detection unit 17, and the failure determination unit 18 may be achieved by a semiconductor integrated circuit into which a computer program for achieving the functions of the respective units is written.

Next, determination of whether or not the insulation resistance value detection unit 15 has failed is described in more detail.

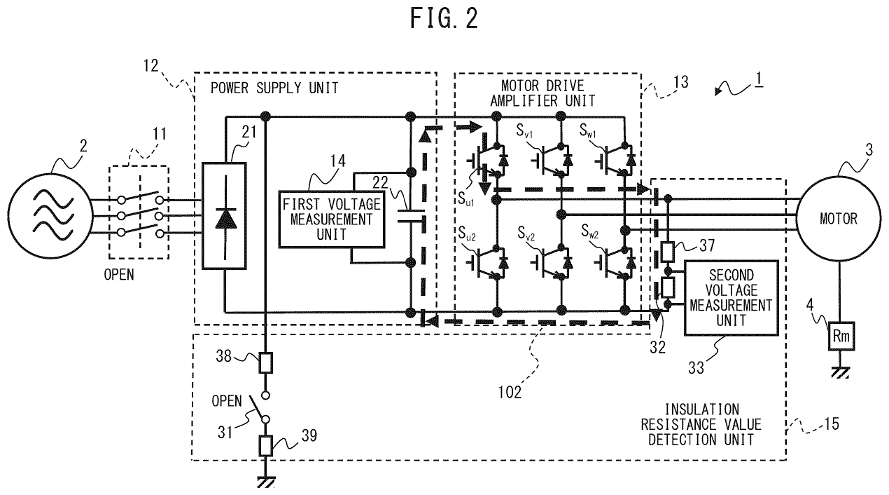

FIG. 2 is a diagram for describing the second closed circuit that is formed when executing the processing of determining whether or not the insulation resistance value detection unit has failed in the motor drive device according to one embodiment of the present disclosure. In FIG. 2, illustrations of the control unit 30, the calculation unit 34, the correction value generation unit 35, the correction unit 36, the voltage estimation unit 16, the error detection unit 17, and the failure determination unit 18 are omitted.

When executing the processing of determining whether or not the insulation resistance value detection unit 15 has failed, firstly, the first switch 11 and the second switch 31 are respectively set in the closed state and the open state, all the switching elements in the motor drive amplifier unit 13 are set in the OFF state, and the capacitor 22 is charged with the electrical power flowing into the capacitor 22 from the AC power supply 2 via the rectifier circuit 21. When charging of the capacitor 22 is completed, a second closed circuit 102 indicated in the figure with an arrow in a bold line is formed by setting the first switch 11 and the second switch 31 in the open state and by switching the switching elements in the upper arm or the lower arm of the motor drive amplifier unit 13 as desired. It should be noted that even when driving of the motor 3 is already stopped after the motor 3 has been driven by the motor drive device 1, since the capacitor 22 is sufficiently charged, the second closed circuit 102 may be formed in this condition by setting the first switch 11 and the second switch 31 in the open state and by switching the switching elements in the upper arm or the lower arm of the motor drive amplifier unit 13 as desired. In the illustrated example, as an example, a switching element Su1 in the upper arm of the U-phase of the motor drive amplifier unit 13 is set in an ON state while other switching elements Su2, Sv1, Sv2, Sw1, and Sw2 are set in an OFF state. Thus, the second closed circuit 102 including the capacitor 22, the switching element Su1, the voltage-dividing resistor 37, and the measuring resistor 32 is formed.

When the second closed circuit 102 is formed, by using the measured value of the voltage of the power supply unit 12 (voltage across the capacitor 22) obtained by the first voltage measurement unit 14, the voltage between the terminals of the measuring resistor 32 can be estimated. Assuming that the resistance value of the measuring resistor 32 is Rb [Ω], the resistance value of the voltage-dividing resistor 37 is Ra [Ω], and the measured value of the voltage of the power supply unit 12 (voltage across the capacitor 22) obtained by the first voltage measurement unit 14 when the second closed circuit 102 is formed is Vdc [V], an estimated value Vin1 [V] of the voltage between the terminals of the measuring resistor 32 can be calculated according to equation 1. it should be noted that although the second closed circuit 102 contains on-resistances of the switching elements (e.g., IGBT) in the motor drive amplifier unit 13, since the values of those on-resistances are very small, the on-resistances of the switching elements are ignored in equation 1 and equations to be described hereinafter.

$$\begin{matrix}[ Math . 1 ] & \\ V i n 1 = V d c \times \frac{Rb}{Ra + Rb} & ( 1 )\end{matrix}$$

The voltage estimation unit 16 calculates the estimated value Vin1 [V] of the voltage between the terminals of the measuring resistor 32 according to equation 1 based on the measured value Vdc [V] of the voltage of the power supply unit 12, which has been obtained by the first voltage measurement unit 14 when the second closed circuit 102 is formed, the resistance value Rb [Ω] of the measuring resistor 32, and the resistance value Ra [Ω] of the voltage-dividing resistor 37. The resistance value Rb [Ω] of the measuring resistor 32 and the resistance value Ra [Ω] of the voltage-dividing resistor 37 are known, and, for example, nominal values of these components defined by the manufacturer may be used. The resistance value Rb [Ω] of the measuring resistor 32 and the resistance value Ra [Ω] of the voltage-dividing resistor 37 may be input in advance to the arithmetic processing unit constituting the voltage estimation unit 16 to be used in calculation of the estimated value Vin1 [V] of the voltage between the terminals of the measuring resistor 32 by the voltage estimation unit 16.

In addition, when the second closed circuit 102 is formed as described, a value Vin2 [V] of the voltage between the terminals of the measuring resistor 32 (actual measured value) can be measured by the second voltage measurement unit 33.

When the second closed circuit 102 is formed, the estimated value Vin1 [V] of the voltage between the terminals of the measuring resistor 32 and the measured value (actual measured value) Vin2 [V] of the voltage between the terminals of the measuring resistor 32 are ideally identical. Actually, there is an error between these values caused by variations and aging of components, i.e., the second voltage measurement unit 33, the measuring resistor 32, and the voltage-dividing resistor 37 that constitute the isolated amplifier. An error ΔV [V] between the estimated value Vin1 [V] of the voltage between the terminals of the measuring resistor 32 and the measured value Vin2 (actual measured value) [V] of the voltage between the terminals of the measuring resistor 32 is given by equation 2.

$$\begin{matrix}[ Math . 2 ] & \\ ΔV = V i n 1 - V i n 2 & ( 2 )\end{matrix}$$

The error detection unit 17 detects, according to equation 2, the error ΔV [V] between the measured value Vin2 [V] of the voltage between the terminals of the measuring resistor 32, which has been obtained by the second voltage measurement unit 33 when the second closed circuit 102 is formed, and the estimated value Vin1 [V] of the voltage between the terminals of the measuring resistor 32, which has been calculated by the voltage estimation unit 16. The error ΔV [V] detected by the error detection unit 17 is used in the failure determination processing by the failure determination unit 18.

The failure determination unit 18 determines that the insulation resistance value detection unit 15 has failed when the error ΔV [V] detected by the error detection unit 17 is out of the predefined reference error range and determines that the insulation resistance value detection unit 15 has not failed when the error ΔV [V] detected by the error detection unit 17 is within the reference error range. Assuming, for example, that a lower limit of the reference error range is Vth1 [V] and an upper limit is Vth2 [V], equation 3 to be used in the failure determination processing by the failure determination unit 18 is obtained.

$$\begin{matrix}[ Math . 3 ] & \\ V th 1 < ΔV < V th 2 & ( 3 )\end{matrix}$$

The failure determination unit 18 determines, for example, according to equation 3, whether or not the insulation resistance value detection unit 15 has failed on the basis of the error detected by the error detection unit 17.

It should be noted that the lower limit Vth1 [V] and the upper limit Vth2 [V] of the reference error range used in the failure determination processing by the failure determination unit 18 have a relationship of “Vth1<Vth2”, and each of them can be a positive or negative value. The lower limit Vth1 [V] and the upper limit Vth2 [V] of the reference error range may be appropriately set, for example, by actuating the motor drive device 1 experimentally or in an actual operation, or by determining in advance, by means of computer simulation, a relationship among an operating environment of the isolated amplifier including the second voltage measurement unit 33, an operating environment of the motor drive device 1, and whether or not an alarm signal is output by the motor drive device 1, or the like. The lower limit Vth1 [V] and the upper limit Vth2 [V] of the reference error range may be stored in a rewritable storage unit (not illustrated) and may be rewritten by an external device, which allows the lower limit Vth1 [V] and the upper limit Vth2 [V] of the reference error range to be changed to an appropriate value as necessary even after it is already set. The storage unit that stores the lower limit Vth1 [V] and the upper limit Vth2 [V] of the reference error range may be, for example, configured using an electrically erasable and recordable non-volatile memory such as EEPROM (registered trademark) or high-speed readable/writable random access memory such as DRAM or SRAM. The lower limit Vth1 [V] and the upper limit Vth2 [V] of the reference error range, which have been already set, may be input in advance to the arithmetic processing unit constituting the failure determination unit 18 to be used in the failure determination processing by the failure determination unit 18.

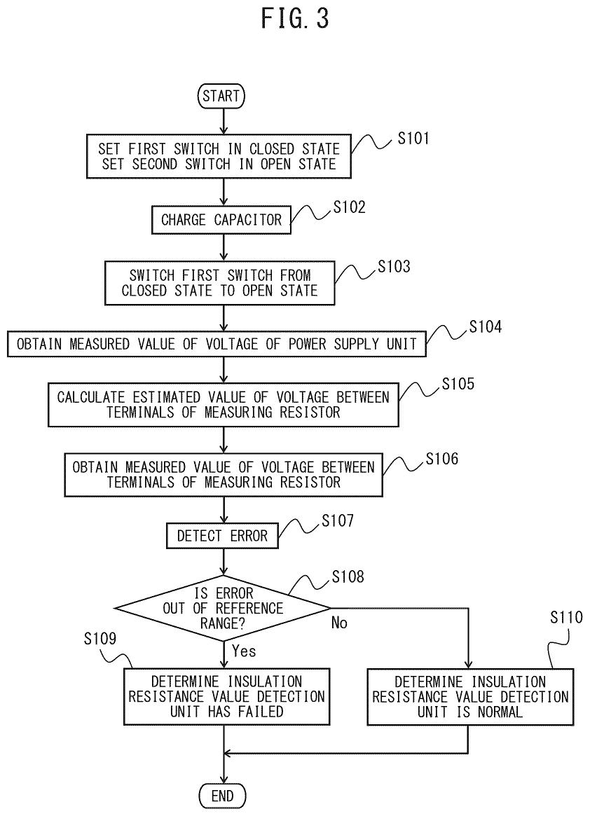

FIG. 3 is a flowchart illustrating operation sequences in the processing of determining whether or not the insulation resistance value detection unit has failed in the motor drive device according to one embodiment of the present disclosure.

In step S101, the control unit 30 controls the first switch 11 and the second switch 31 to be in the closed state and the open state respectively. The control unit 30 also controls all the switching elements in the motor drive amplifier unit 13 to be in the OFF state. With this operation, in step S102, the capacitor 22 is charged with the electrical power flowing into the capacitor 22 from the AC power supply 2 via the rectifier circuit 21. The charging status of the capacitor 22 is monitored by the control unit 30 via the first voltage measurement unit 14. It should be noted that when there is a state the motor 3 that has been driven by the motor drive device 1 is stopped, since the capacitor 22 is sufficiently charged, step S102 may be omitted.

When charging of the capacitor 22 is completed, in step S103, the control unit 30 switches the first switch 11 from the closed state to the open state and sets the first switch 11 and the second switch 31 to be in the open state. The control unit 30 also performs switching of the switching elements in the upper arm or the lower arm of the motor drive amplifier unit 13 as desired. In the example illustrated in FIG. 2, as an example, the switching element Su1 in the upper arm of the U-phase of the motor drive amplifier unit 13 is set in the ON state while other switching elements Su2, Sv1, Sv2, Sw1, and Sw2 are set in the OFF state. Thus, the second closed circuit 102 including the capacitor 22, the switching element Su1, the voltage-dividing resistor 37, and the measuring resistor 32 is formed.

In step S104, the first voltage measurement unit 14 obtains the measured value of the voltage of the power supply unit 12 (voltage across the capacitor 22).

In step S105, the voltage estimation unit 16 calculates the estimated value Vin1 [V] of the voltage between the terminals of the measuring resistor 32 according to equation 1 based on the measured value Vdc [V] of the voltage of the power supply unit 12, which has been obtained by the first voltage measurement unit 14 when the second closed circuit 102 is formed, the resistance value Rb [Ω] of the measuring resistor 32, and the resistance value Ra [Ω] of the voltage-dividing resistor 37.

In step S106, the second voltage measurement unit 33 obtains the measured value Vin2 [V] of the voltage between the terminals of the measuring resistor 32 when the second closed circuit 102 is formed.

Execution sequences of steps S104 to S106 may be appropriately changed as long as there is no inconsistency. For example, steps S104 and S105 may be executed after step S106 is executed; alternatively, step S106 may be executed between step S104 and step S105. It should be noted that step S105 should be executed at least after step S104.

In step S107, the error detection unit 17 detects, according to equation 2, the error ΔV [V] between the measured value Vin2 [V] of the voltage between the terminals of the measuring resistor 32, which has been obtained by the second voltage measurement unit 33 when the second closed circuit 102 is formed, and the estimated value Vin1 [V] of the voltage between the terminals of the measuring resistor 32, which has been calculated by the voltage estimation unit 16.

In step S108, the failure determination unit 18 determines whether or not the error ΔV [V] detected by the error detection unit 17 is out of the predefined reference error range. In step S108, when the failure determination unit 18 determines that the error ΔV [V] is out of the predefined reference error range, the process proceeds to step S109 and the failure determination unit 18 determines that the insulation resistance value detection unit 15 has failed. In step S108, when the failure determination unit 18 determines that the error ΔV [V] is not out of the predefined reference error range (in other words, when the error ΔV [V] is within the predefined reference error range), the process proceeds to step S110 and the failure determination unit 18 determines that the insulation resistance value detection unit 15 has not failed.

Next, detection of the insulation resistance value Rm [Ω] of the insulation resistor 4 of the motor 3 by the insulation resistance value detection unit 15 is described in more detail.

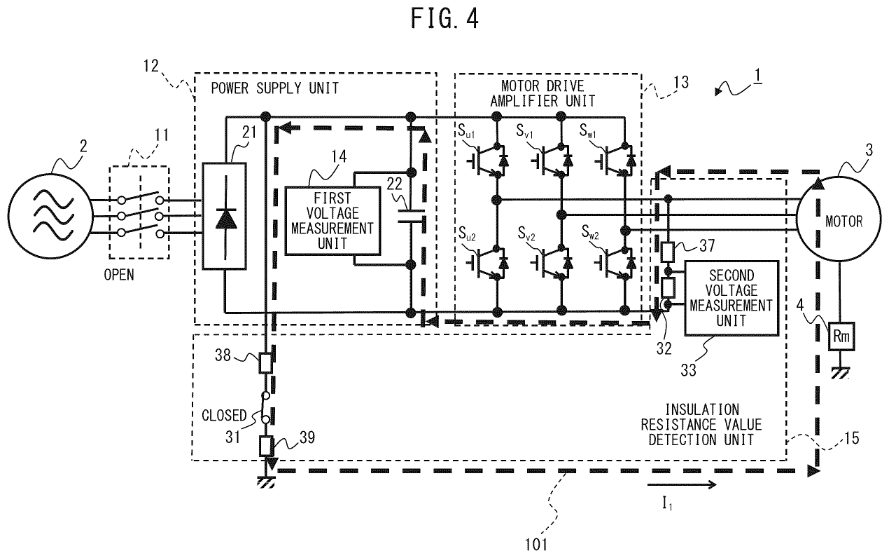

FIG. 4 is a diagram describing the first closed circuit that is formed when executing the processing of detecting the insulation resistance value by the insulation resistance value detection unit in the motor drive device according to one embodiment of the present disclosure. In FIG. 4, illustrations of the control unit 30, the calculation unit 34, the correction value generation unit 35, the correction unit 36, the voltage estimation unit 16, the error detection unit 17, and the failure determination unit 18 are omitted.

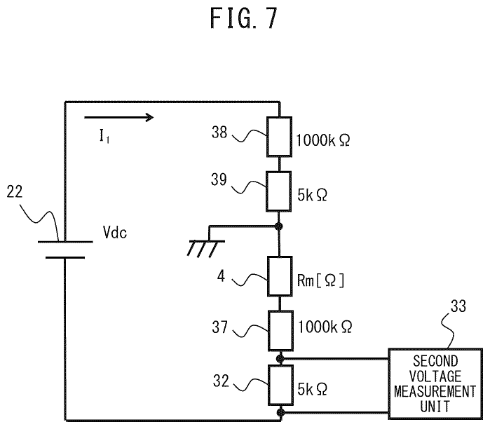

When the processing of detecting the insulation resistance value is executed by the insulation resistance value detection unit 15, firstly, the first switch 11 and the second switch 31 are respectively set in the closed state and the open state, all the switching elements in the motor drive amplifier unit 13 are set in the OFF state, and the capacitor 22 is charged with the electrical power flowing into the capacitor 22 from the AC power supply 2 via the rectifier circuit 21. When charging of the capacitor 22 is completed, the first closed circuit 101 indicated in the figure with an arrow in a bold line is formed by setting the first switch 11 and the second switch 31 in the open state and the closed state respectively and by setting all the switching elements in the upper arm and the lower arm of the motor drive amplifier unit 13 in the OFF state as desired. FIG. 7 is a circuit diagram in which a portion related to the first closed circuit is depicted. In FIG. 7, illustration of the second switch 31 in the closed state is omitted. As illustrated in FIG. 4 and FIG. 7, the first closed circuit 101 includes the capacitor 22, the voltage-dividing resistor 38, the second switch 31 in the closed state, the voltage-dividing resistor 39, the insulation resistor 4 of the motor coil of the motor 3, the voltage-dividing resistor 37, and the measuring resistor 32.

When the first closed circuit 101 is formed, a leak current I₁ [A] that flows through the first closed circuit 101 can be calculated according to equation 4 based on the measured value (actual measured value) Vin3 [V] of the voltage between the terminals of the measuring resistor 32 obtained by the second voltage measurement unit 33 and the resistance value Rb [Ω] of the measuring resistor 32.

$$\begin{matrix}[ Math . 4 ] & \\ {I}_{1} = \frac{V i n 3}{Rb} & ( 4 )\end{matrix}$$

When the first closed circuit 101 is formed, with the measured value Vdc [V] of the voltage of the power supply unit 12 (voltage across the capacitor 22) obtained by the first voltage measurement unit 14, the leak current I₁ [A] that flows through the first closed circuit 101, the resistance value Rb [Ω] of the measuring resistor 32, the resistance value Ra [Ω] of the voltage-dividing resistor 37, the resistance value Rc [Ω] of the voltage-dividing resistor 38, the resistance value Rd [Ω] of the voltage-dividing resistor 39, and the insulation resistance value Rm [Ω] of the insulation resistor 4 of the motor 3, a circuit equation as expressed by equation 5 holds.

$$\begin{matrix}[ Math . 5 ] & \\ V d c = ( Rc + Rd + Rm + Ra + Rb ) \times {I}_{1} & ( 5 )\end{matrix}$$

By substituting equation 5 into equation 4 and some modification, equation 6 is obtained.

$$\begin{matrix}[ Math . 6 ] & \\ Rm = \frac{V d c}{V i n 3} \times Rb - ( Rc + Rd + Ra + Rb ) & ( 6 )\end{matrix}$$

According to equation 6, the insulation resistance value Rm [Ω] of the insulation resistor 4 of the motor 3 can be calculated. It should be noted that the output from the second voltage measurement unit 33 contains the error ΔV caused by variations and aging of components, i.e., the second voltage measurement unit 33, the measuring resistor 32, and the voltage-dividing resistor 37 that constitute the isolated amplifier. Therefore, a value “−ΔV [V]” obtained by inverting the polarity of the error ΔV [V] is used as the correction value Vamend [V] for correcting the measured value Vin3 [V] of the voltage between the terminals of the measuring resistor 32 obtained by the second voltage measurement unit 33 when the first closed circuit 101 is formed. The error ΔV used here for generating the correction value Vamend [V] is the one that is used when it is determined that the error ΔV [V] is within the reference error range, in other words, when the failure determination unit 18 determines that the insulation resistance value detection unit 15 has not failed. The correction value Vamend [V] is given by equation 7 using the error ΔV [V] that is used when the failure determination unit 18 determines that the insulation resistance value detection unit 15 has not failed. Since the offset error is more dominant than the gain error in the error ΔV, in the present embodiment, as an example, the correction value Vamend [V] to be added to the measured value Vin3 [V] of the voltage between the terminals of the measuring resistor 32 obtained by the second voltage measurement unit 33 when the first closed circuit 101 is formed is generated as expressed by equation 7 for canceling out the offset error.

$$\begin{matrix}[ Math . 7 ] & \\ V amend = - ΔV & ( 7 )\end{matrix}$$

The correction value generation unit 35 generates the correction value Vamend [V] according to equation 7 using the error ΔV [V] that is used when the failure determination unit 18 determines that the insulation resistance value detection unit 15 has not failed.

By adding the correction value Vamend [V] to the measured value Vin3 [V] of the voltage between the terminals of the measuring resistor 32, which has been obtained by the second voltage measurement unit 33 when the first closed circuit 101 is formed, a corrected value Vin4 [V] of the measured value of the voltage between the terminals of the measuring resistor 32 is obtained as expressed by equation 8.

$$\begin{matrix}[ Math . 8 ] & \\ V i n 4 = V i n 3 + V amend & ( 8 )\end{matrix}$$

The correction unit 36 corrects, according to equation 8, the measured value Vin3 [V] of the voltage between the terminals of the measuring resistor 32, which has been obtained by the second voltage measurement unit 33 when the first closed circuit 101 is formed, using the correction value Vamend [V] generated by the correction value generation unit 35, and generates the corrected value Vin4 [V] of the measured value of the voltage between the terminals of the measuring resistor 32.

By replacing the measured value Vin3 [V] of the voltage between the terminals of the measuring resistor 32 with the corrected value Vin4 [V] of the measured value of the voltage between the terminals of the measuring resistor 32 in equation 6, equation 9 is obtained, and accuracy of the insulation resistance value Rm [Ω] of the insulation resistor 4 of the motor 3 is improved by calculating the insulation resistance value Rm [Ω] according to equation 9.

$$\begin{matrix}[ Math . 9 ] & \\ Rm = \frac{V d c}{V i n 4} \times Rb - ( Rc + Rd + Ra + Rb ) & ( 9 )\end{matrix}$$

The calculation unit 34 calculates, when the failure determination unit 18 determines that the insulation resistance value detection unit 15 has not failed, the insulation resistance value Rm [Ω] of the insulation resistor 4 of the motor 3 according to equation 9 based on the measured value Vdc [V] of the voltage of the power supply unit 12, which has been obtained by the first voltage measurement unit 14 when the first closed circuit 101 is formed, the corrected value Vin4 [V] of the measured value of the voltage between the terminals of the measuring resistor 32, and at least the resistance value Rb [Ω] of the measuring resistor 32. More specifically, in the examples illustrated in FIG. 1 and FIG. 4, the calculation unit 34 calculates, when the failure determination unit 18 determines that the insulation resistance value detection unit 15 has not failed, the insulation resistance value Rm [Ω] of the insulation resistor 4 of the motor 3 according to equation 9 based on the measured value Vdc [V] of the voltage of the power supply unit 12, which has been obtained by the first voltage measurement unit 14 when the first closed circuit 101 is formed, the corrected value Vin4 [V] of the measured value of the voltage between the terminals of the measuring resistor 32, the resistance value Rb [Ω] of the measuring resistor 32, the resistance value Ra [Ω] of the voltage-dividing resistor 37, the resistance value Rc [Ω] of the voltage-dividing resistor 38, and the resistance value Rd [Ω] of the voltage-dividing resistor 39. On the other hand, when the failure determination unit 18 determines that the insulation resistance value detection unit 15 has failed, the processing of detecting the insulation resistance value by the insulation resistance value detection unit 15 is not executed and the process is terminated.

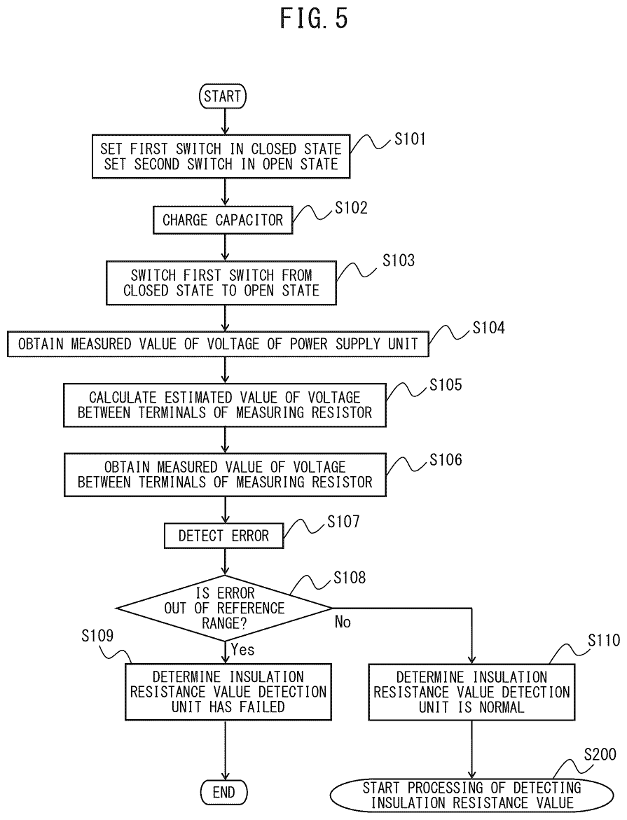

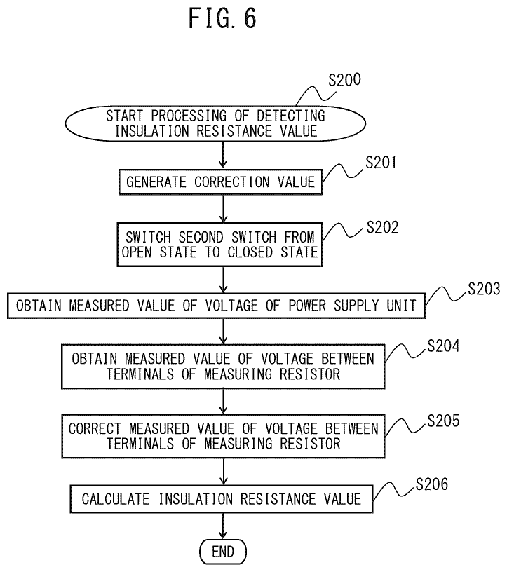

FIG. 5 is a flowchart (part 1) illustrating operation sequences in the processing of detecting the insulation resistance value by the insulation resistance value detection unit in the motor drive device according to one embodiment of the present disclosure while FIG. 6 is a flowchart (part 2) illustrating operation sequences in the processing of detecting the insulation resistance value by the insulation resistance value detection unit in the motor drive device according to one embodiment of the present disclosure.

The operations in steps S101 to S110 illustrated in FIG. 5 are respectively identical to those in steps S101 to S110 illustrated in FIG. 3.

In step S108, when the failure determination unit 18 determines that the error ΔV [V] is not out of the reference error range (in other words, when the error ΔV [V] is within the reference error range), the process proceeds to step S110 and the failure determination unit 18 determines that the insulation resistance value detection unit 15 has not failed.

In step S200 that follows step S110, the insulation resistance value detection unit 15 starts the processing of detecting the insulation resistance value.

Since capacitance of the capacitor 22 (e.g., an electrolytic capacitor) is generally large, leak current flows only for a short time during the processing of calculating the error in steps S103 to S110, and decrease in the amount of charge in the capacitor 22 is very small. Therefore, when the processing of calculating the insulation resistance value is executed after step S200, recharging of the capacitor 22 is essentially unnecessary; however, recharging of the capacitor 22 may be performed as necessary.

In step S201, the correction value generation unit 35 generates the correction value Vamend [V] according to equation 7 using the error ΔV [V] that is used when the failure determination unit 18 determines that the insulation resistance value detection unit 15 has not failed.

In step S202, the control unit 30 switches the second switch 31 from the open state to the closed state. With this operation, the first switch 11 is in the open state and the second switch 31 is in the closed state. The control unit 30 also sets all the switching elements in the upper arm and the lower arm of the motor drive amplifier unit 13 in the OFF state. As a result, the first closed circuit 101 is formed.

In step S203, the first voltage measurement unit 14 obtains the measured value of the voltage of the power supply unit 12 (voltage across the capacitor 22).

In step S204, the second voltage measurement unit 33 obtains the measured value Vin3 [V] of the voltage between the terminals of the measuring resistor 32 when the first closed circuit 101 is formed.

In step S205, the correction unit 36 corrects, according to equation 8, the measured value Vin3 [V] of the voltage between the terminals of the measuring resistor 32, which has been obtained by the second voltage measurement unit 33 when the first closed circuit 101 is formed, using the correction value Vamend [V] generated by the correction value generation unit 35, and generates the corrected value Vin4 [V] of the measured value of the voltage between the terminals of the measuring resistor 32.

In step S206, the calculation unit 34 calculates, when the failure determination unit 18 determines that the insulation resistance value detection unit 15 has not failed, the insulation resistance value Rm [Ω] of the insulation resistor 4 of the motor 3 according to equation 9 based on the measured value Vdc [V] of the voltage of the power supply unit 12, which has been obtained by the first voltage measurement unit 14 when the first closed circuit 101 is formed, the corrected value Vin4 [V] of the measured value of the voltage between the terminals of the measuring resistor 32, and at least the resistance value Rb [Ω] of the measuring resistor 32. More specifically, in the examples illustrated in FIG. 1 and FIG. 4, the calculation unit 34 calculates, when the failure determination unit 18 determines that the insulation resistance value detection unit 15 has not failed, the insulation resistance value Rm [Ω] of the insulation resistor 4 of the motor 3 according to equation 9 based on the measured value Vdc [V] of the voltage of the power supply unit 12, which has been obtained by the first voltage measurement unit 14 when the first closed circuit 101 is formed, the corrected value Vin4 [V] of the measured value of the voltage between the terminals of the measuring resistor 32, the resistance value Rb [Ω] of the measuring resistor 32, the resistance value Ra [Ω] of the voltage-dividing resistor 37, the resistance value Rc [Ω] of the voltage-dividing resistor 38, and the resistance value Rd [Ω] of the voltage-dividing resistor 39.

An effect of the error ΔV [V] caused by variations and aging of components, i.e., the second voltage measurement unit 33, the measuring resistor 32, and the voltage-dividing resistor 37 that constitute the isolated amplifier on the accuracy in detection of the insulation resistance value Rm [Ω] of the motor 3 is described with numerical examples.

For example, numerical examples are considered in which the resistance value Rc of the voltage-dividing resistor 38 is 1000 kΩ, the resistance value Rd of the voltage-dividing resistor 39 is 5 kΩ, the resistance value Rb of the measuring resistor 32 is 5 kΩ, the resistance value Ra of the voltage-dividing resistor 37 is 1000 kΩ, and the voltage Vdc of the power supply unit 12 (voltage across the capacitor 22) is 300 V.

When an actual value of the insulation resistance value Rm of the motor 3 is 1 MΩ, the voltage between the terminals of the measuring resistor 32 when the first closed circuit 101 is formed is, as a result of calculation according to equation 6, 498 mV. If an error ΔV of 10 mV is contained in the measured value Vin3 of the voltage between the terminals of the measuring resistor 32 obtained by the second voltage measurement unit 33, i.e., 498 mV, a correct value of the measured value Vin3 of the voltage between the terminals of the measuring resistor 32 should be 488 mV; when recalculation is made by assigning 488 mV to Vin3 (Vin3=488 mV) in equation 6, the insulation resistance value Rm of the motor 3 is 1.06 MΩ, which is different from the actual value of the insulation resistance value Rm of the motor 3, i.e., 1 MΩ.

When an actual value of the insulation resistance value Rm of the motor 3 is 10 MΩ, the voltage between the terminals of the measuring resistor 32 when the first closed circuit 101 is formed is, as a result of calculation according to equation 6, 125 mV. If an error ΔV of 10 mV is contained in the measured value Vin3 of the voltage between the terminals of the measuring resistor 32 obtained by the second voltage measurement unit 33, i.e., 125 mV, a correct value of the measured value Vin3 of the voltage between the terminals of the measuring resistor 32 should be 115 mV; when recalculation is made by assigning 115 mV to Vin3 (Vin3=115 mV) in equation 6, the insulation resistance value Rm of the motor 3 is 11.03 MΩ, which is different from the actual value of the insulation resistance value Rm of the motor 3, i.e., 10 MΩ.

When an actual value of the insulation resistance value Rm of the motor 3 is 50 MΩ, the voltage between the terminals of the measuring resistor 32 when the first closed circuit 101 is formed is, as a result of calculation according to equation 6, 29 mV. If an error ΔV of 10 mV is contained in the measured value Vin3 of the voltage between the terminals of the measuring resistor 32 obtained by the second voltage measurement unit 33, i.e., 29 mV, a correct value of the measured value Vin3 of the voltage between the terminals of the measuring resistor 32 should be 19 mV; when recalculation is made by assigning 19 mV to Vin3 (Vin3=19 mV) in equation 6, the insulation resistance value Rm of the motor 3 is 76.94 MΩ, which is different from the actual value of the insulation resistance value Rm of the motor 3, i.e., 50 MΩ.

As indicated by the numerical examples described above, as the actual value of the insulation resistance value Rm [Ω] of the motor 3 is larger, the insulation resistance value of the motor 3 will contain a larger error when it is calculated in a condition where the error ΔV is contained in the measured value Vin3 of the voltage between the terminals of the measuring resistor 32 obtained by the second voltage measurement unit 33 when the first closed circuit 101 is formed. According to the present embodiment, the measured value Vin3 [V] of the voltage [V] between the terminals of the measuring resistor 32 obtained by the second voltage measurement unit 33 is corrected using the value “−ΔV [V]” obtained by inverting the polarity of the error ΔV as the correction value Vamend [V] and the insulation resistance value Rm [Ω] is calculated using the corrected value Vin4 [V] of the measured value of the voltage [V] between the terminals of the measuring resistor 32; therefore, the insulation resistance value Rm [Ω] of the motor 3 can be correctly detected.

As described above, the motor drive device 1 according to one embodiment of the present disclosure executes the failure determination processing on the basis of the error ΔV [V] caused by variations and aging of components, i.e., the second voltage measurement unit 33, the measuring resistor 32, and the voltage-dividing resistor 37, therefore, the motor drive device 1 can correctly detect a failure of the insulation resistance value detection unit 15 that detects the insulation resistance value of the motor 3. In addition, the motor drive device 1 corrects the measured value Vin3 [V] of the measuring resistor 32 by the second voltage measurement unit 33 using the error ΔV [V] that is used when the failure determination unit 18 determines that the insulation resistance value detection unit 15 has not failed and calculates the insulation resistance value Rm [Ω] of the motor 3 based on the corrected value Vin4 [V] of the measured value of the measuring resistor 32; therefore, the insulation resistance value Rm [Ω] of the motor 3 can be correctly detected.

Next, a variation example of the motor drive device 1 according to one embodiment of the present disclosure is described.

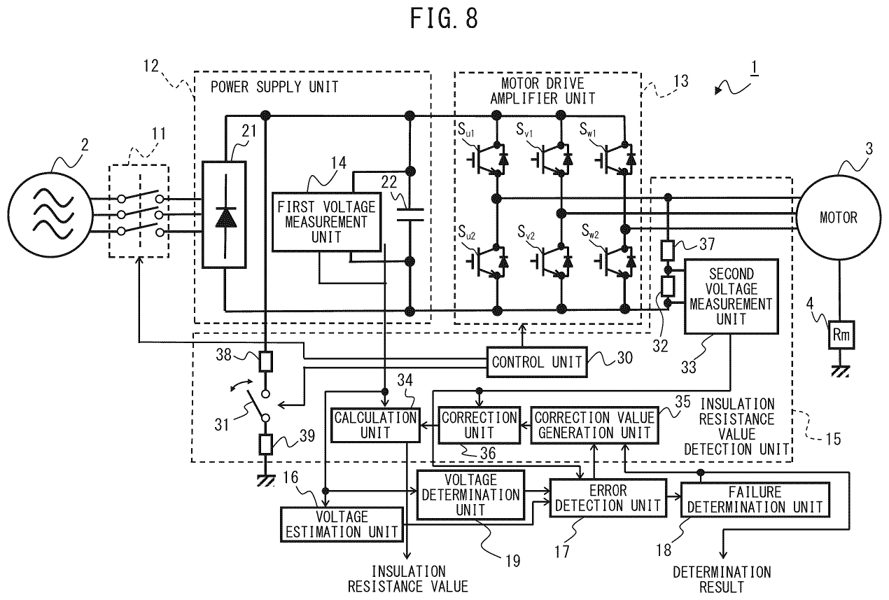

FIG. 8 is a diagram illustrating the variation example of the motor drive device according to one embodiment of the present disclosure.

In the first closed circuit 101 illustrated in FIG. 4 and FIG. 7 that is used for the processing of detecting the insulation resistance value by the insulation resistance value detection unit 15, the voltage Vdc [V] of the power supply unit 12 (voltage across the capacitor 22) is applied to a combined resistance obtained from the voltage-dividing resistor 39, the voltage-dividing resistor 39, the insulation resistor 4 of the motor 3, the voltage-dividing resistor 37, and the measuring resistor 32, leak current I₁ [A] that flows through the first closed circuit 101 is therefore very small. Accordingly, by narrowing an input voltage range of the isolated amplifier consisting of the measuring resistor 32, the second voltage measurement unit 33, and the voltage-dividing resistor 37, detection resolution of the second voltage measurement unit 33 is secured. In contrast, in the second closed circuit 102 illustrated in FIG. 2 that is used for the processing of determining whether or not the insulation resistance value detection unit 15 has failed, the voltage Vdc [V] of the power supply unit 12 (voltage across the capacitor 22) is applied to a combined resistance obtained from the voltage-dividing resistor 37 and the measuring resistor 32, electric current that flows through the second closed circuit 102 is therefore larger than the leak current I₁ [A] that flows through the first closed circuit 101. Consequently, when an isolated amplifier having a small input voltage range is used for ensuring the detection resolution of the second voltage measurement unit 33, during the processing of determining whether or not the insulation resistance value detection unit 15 has failed, the voltage applied to the measuring resistor 32 may exceed the input voltage range of the isolated amplifier, and the processing of determining whether or not the insulation resistance value detection unit 15 has failed may not be correctly executed. On the other hand, when an isolated amplifier having a large input voltage range is used for correctly executing the processing of determining whether or not the insulation resistance value detection unit 15 has failed, the detection resolution of the second voltage measurement unit 33 may be reduced.

To solve such problems, in the variation example of the motor drive device according to one embodiment of the present disclosure, before executing the processing of determining whether or not the insulation resistance value detection unit 15 has failed, the first switch 11 and the second switch 31 are set in the open state and all the switching elements in the upper arm and the lower arm of the motor drive amplifier unit 13 are set in the OFF state, and a discharge circuit consisting of the capacitor 22 and the first voltage measurement unit 14 is formed. Since the first voltage measurement unit 14 is constructed from, for example, a measuring resistor (not illustrated), a voltage-dividing resistor (not illustrated), and an isolated amplifier, by forming the discharge circuit, the charge in the capacitor 22 may be discharged by means of the measuring resistor (not illustrated) and the voltage-dividing resistor (not illustrated) in the first voltage measurement unit 14. Then, after the voltage Vdc [V] of the power supply unit 12 (voltage across the capacitor 22) is reduced to a predefined reference voltage or below, the second closed circuit 102 is formed again, and the second voltage measurement unit is caused to obtain the measured value Vin2 [V] of the voltage between the terminals of the measuring resistor 32.

The motor drive device 1 according to the present variation example further includes a voltage determination unit 19. The voltage determination unit 19 determines whether or not the measured value Vdc [V] of the voltage of the power supply unit 12 (voltage across the capacitor 22) obtained by the first voltage measurement unit 14 when the first switch 11 and the second switch 31 are set in the open state and all the switching elements in the upper arm and the lower arm of the motor drive amplifier unit 13 are set in the OFF state is reduced to the predefined reference voltage Vth3 [V] or below. The voltage determination unit 19 is included in the arithmetic processing unit, and the voltage determination unit 19 is a functional module achieved by, for example, a computer program executed by the processor. When the voltage determination unit 19 is built, for example, in the form of a computer program, a function of the voltage determination unit 19 may be achieved by causing the arithmetic processing unit to operate in accordance with the computer program. The computer program for executing processing by the voltage determination unit 19 may be recorded on and supplied in the form of a computer-readable recording medium, such as a semiconductor memory, a magnetic recording medium, or an optical recording medium. Alternatively, the voltage determination unit 19 may be achieved by a semiconductor integrated circuit into which a computer program for achieving the function of the voltage determination unit 19 is written.

When the first switch 11 and the second switch 31 are set in the open state and all the switching elements in the upper arm and the lower arm of the motor drive amplifier unit 13 are set in the OFF state, after the voltage determination unit 19 determines that the measured value Vdc [V] of the voltage of the power supply unit 12 (voltage across the capacitor 22) obtained by the first voltage measurement unit 14 is reduced to the reference value Vth3 [V] or below, the second closed circuit 102 is formed again, and the second voltage measurement unit 33 obtains a measured value of the voltage between the terminals of the measuring resistor 32.

It should be noted that the reference voltage Vth3 [V] used in the voltage determination processing by the voltage determination unit 19 may be set depending on the isolated amplifier having an input voltage range that can ensure a desired detection resolution of the second voltage measurement unit 33. The reference voltage Vth3 [V] may be stored in a rewritable storage unit (not illustrated) and may be rewritten by an external device, which allows the reference voltage Vth3 [V] to be changed to an appropriate value as necessary even after it is already set. The storage unit that stores the reference voltage Vth3 [V] may be, for example, configured using an electrically erasable and recordable non-volatile memory such as EEPROM (registered trademark) or high-speed readable/writable random access memory such as DRAM or SRAM. The reference voltage Vth3 [V] that has been already set may be input in advance to the arithmetic processing unit constituting the voltage determination unit 19 to be used in the voltage determination processing by the voltage determination unit 19.

Described below is a numerical example of the reference voltage Vth3 [V]. For example, it is assumed that the resistance value Rb of the measuring resistor 32 is 5 kΩ, the resistance value Ra of the voltage-dividing resistor 37 is 1000 kΩ, and the input voltage range of the second voltage measurement unit 33 in the isolated amplifier is, for example, 0 mV to 1000 mV. In this example, if the voltage Vdc [V] of the power supply unit 12 (voltage across the capacitor 22) is 300 V, the voltage Vin2 between the terminals of the measuring resistor 32 when the second closed circuit 102 is formed is, as a result of calculation in accordance with Ohm's law, approximately 1493 mV, and exceeds the upper limit of the input voltage range of the second voltage measurement unit 33. To keep the voltage Vin2 [V] between the terminals of the measuring resistor 32 below the upper limit of 1000 mV of the input voltage range of the second voltage measurement unit 33, the voltage Vdc [V] of the power supply unit 12 (voltage across the capacitor 22) needs to be reduced to approximately 200 V. Therefore, the voltage determination unit 19 just needs to be configured to have the reference voltage Vth3 set to, for example, 200 V. It should be noted that the numerical example described here is just an example.

The configuration of the present variation example of the motor drive device 1 according to the present variation is as described with reference to FIG. 1 except for the voltage determination unit 19 and the second voltage measurement unit 33.

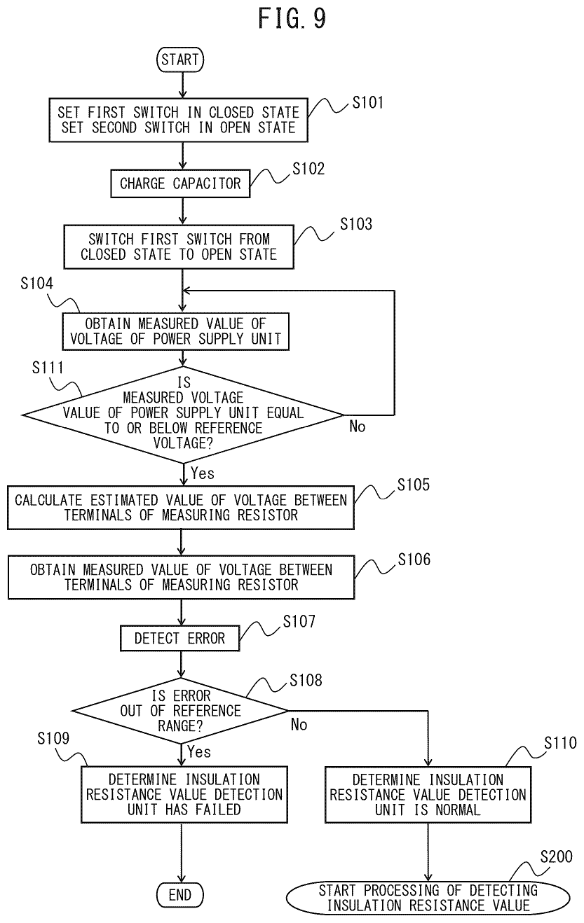

FIG. 9 is a flowchart illustrating operation sequences in the processing of determining whether or not the insulation resistance value detection unit has failed in the variation example of the motor drive device according to one embodiment of the present disclosure.

The operations in steps S101 and S102 illustrated in FIG. 9 are respectively identical to those in steps S101 and S102 illustrated in FIG. 1 and FIG. 3. After charging of the capacitor 22 in step S102 is completed, in step S103, the control unit 30 switches the first switch 11 from the closed state to the open state and sets the first switch 11 and the second switch 31 to be in the open state, and controls all the switching elements in the upper arm and the lower arm of the motor drive amplifier unit 13 to be in the OFF state; thus, the control unit 30 forms the discharge circuit consisting of the capacitor 22 and the first voltage measurement unit 14. By forming the discharge circuit, the capacitor 22 is gradually discharged by means of the measuring resistor (not illustrated) and the voltage-dividing resistor (not illustrated) in the first voltage measurement unit 14. In step S104, the first voltage measurement unit 14 obtains the measured value of the voltage of the power supply unit 12 (voltage across the capacitor 22).

In step S111 that follows step S104, the voltage determination unit 19 determines whether or not the measured value Vdc [V] of the voltage of the power supply unit 12 (voltage across the capacitor 22) obtained by the first voltage measurement unit 14 is reduced to the predefined reference voltage Vth3 [V] or below. In step S111, when the voltage determination unit 19 determines that the measured value Vdc [V] of the voltage of the power supply unit 12 (voltage across the capacitor 22) is not reduced to the predefined reference voltage Vth3 [V] or below, the process returns to step S104; when the voltage determination unit 19 determines in step S111 that the measured value Vdc [V] of the voltage of the power supply unit 12 (voltage across the capacitor 22) is reduced to the predefined reference voltage Vth3 [V] or below, the second closed circuit 102 is formed by switching the switching elements in the motor drive amplifier unit 13 as desired, and the process proceeds to step S105. Until the measured value Vdc [V] of the voltage of the power supply unit 12 (voltage across the capacitor 22) is reduced to the predefined reference voltage Vth3 [V] or below by discharging the capacitor 22, steps S104 and S111 are repeatedly performed.

The operations in steps S105 to S110 and S200 illustrated in FIG. 9 are respectively identical to those in steps S105 to S110 and S200 illustrated in FIG. 3. After the operation in step S200 illustrated in FIG. 9, steps S201 to S206 illustrated in FIG. 6 are additionally performed.

As described above, since the variation example of the motor drive device 1 according to one embodiment of the present disclosure can secure an effective detection resolution of the second voltage measurement unit 33, the motor drive device 1 can correctly detect a failure of a circuit of the motor 3 of the insulation resistance value detection unit 15 that detects the insulation resistance value of the motor 3 and can further accurately detect the insulation resistance value Rm [Ω] of the motor 3.

### REFERENCE SIGNS LIST

1 Motor drive device
2 AC power supply
3 Motor
4 Insulation resistor
11 First switch
12 Power supply unit
13 Motor drive amplifier unit
14 First voltage measurement unit
15 Insulation resistance value detection unit
16 Voltage estimation unit
17 Error detection unit
18 Failure determination unit
19 Voltage determination unit
21 Rectifier circuit
22 Capacitor
30 Control unit
31 Second switch
32 Measuring resistor
33 Second voltage measurement unit
34 Calculation unit
35 Correction value generation unit
36 Correction unit
37, 38, 39 Voltage-dividing resistor
101 First closed circuit
102 Second closed circuit

1. A motor drive device, comprising:
a first switch configured to open/close an electrical path from an AC power supply;
a power supply unit configured to rectify an AC voltage supplied from the AC power supply via the first switch in a closed state into a DC voltage with a rectifier circuit and smooth the rectified DC voltage with a capacitor;
a motor drive amplifier unit configured to convert the DC voltage from the power supply unit into an AC voltage for driving a motor using switching elements in an upper arm and a lower arm and supply the AC voltage to the motor;
a first voltage measurement unit configured to obtain a measured value of a voltage of the power supply unit;
an insulation resistance value detection unit including a second switch configured to connect one end of the capacitor to the ground in the closed state and disconnect the one end of the capacitor from the ground in an open state, a measuring resistor placed between the other end of the capacitor and a motor coil, a second voltage measurement unit configured to obtain a measured value of a voltage between terminals of the measuring resistor, and a calculation unit configured to calculate an insulation resistance value of the motor based on the measured value of the voltage of the power supply unit obtained by the first voltage measurement unit, the measured value of the voltage between the terminals of the measuring resistor obtained by the second voltage measurement unit, and a resistance value of the measuring resistor, the measured value of the voltage of the power supply unit and the measured value of the voltage between the terminals of the measuring resistor being obtained when a first closed circuit is formed by setting the first switch and the second switch in the open state and the closed state respectively, the first closed circuit including the second switch, the capacitor, the measuring resistor, the motor coil, and the ground;
a voltage estimation unit configured to calculate an estimated value of the voltage between the terminals of the measuring resistor based on the measured value of the voltage of the power supply unit obtained by the first voltage measurement unit and the resistance value of the measuring resistor, the measured value of the voltage of the power supply unit being obtained when a second closed circuit including the capacitor and the measuring resistor is formed by setting the first switch and the second switch in the open state and by switching the switching elements of the upper arm or the lower arm of the motor drive amplifier unit as desired;
an error detection unit configured to detect an error between the measured value of the voltage between the terminals of the measuring resistor, which has been obtained by the second voltage measurement unit when the second closed circuit is formed and the estimated value of the voltage between the terminals of the measuring resistor, which has been calculated by the voltage estimation unit; and
a failure determination unit configured to determine whether or not the insulation resistance value detection unit has failed on the basis of the error detected by the error detection unit.

2. The motor drive device according to claim 1, wherein the failure determination unit determines that the insulation resistance value detection unit has failed when the error detected by the error detection unit is out of a predefined reference error range and determines that the insulation resistance value detection unit has not failed when the error detected by the error detection unit is within the reference error range.

3. The motor drive device according to claim 2, wherein the insulation resistance value detection unit further includes:
a correction value generation unit configured to generate a correction value based on an error detected by the error detection unit that is used when the failure determination unit determines that the insulation resistance value detection unit has not failed; and
a correction unit configured to correct the measured value of the voltage between the terminals of the measuring resistor, which has been obtained by the second voltage measurement unit when the first closed circuit is formed, using the correction value generated by the correction value generation unit, and generate a corrected value of the measured value of the voltage between the terminals of the measuring resistor,
wherein the calculation unit detects, the insulation resistance value of the motor based on the measured value of the voltage of the power supply unit, which has been obtained by the first voltage measurement unit when the first closed circuit is formed, the corrected value of the measured value of the voltage between the terminals of the measuring resistor, and the resistance value of the measuring resistor.

4. The motor drive device according to claim 3, further comprising:
a voltage determination unit configured to determine whether or not the measured value of the voltage of the power supply unit, which has been obtained by the first voltage measurement unit is reduced to a predefined reference voltage or below,
wherein, when the first switch and the second switch are set in the open state and all the switching elements in the upper arm and the lower arm of the motor drive amplifier unit are set in an OFF state, after the voltage determination unit determines that the measured value of the voltage of the power supply unit, which has been obtained by the first voltage measurement unit is reduced to the reference value or below, the second voltage measurement unit obtains a measured value of the voltage between the terminals of the measuring resistor when the second closed circuit is formed.
